(19) United States
(12) Patent Application Publication
(10) Pub. No.: US 2023/0083002 A1
(43) Pub. Date: Mar. 16, 2023

(54) POLYMER FILM AND METHOD OF PRODUCING SAME, AND LAMINATE

(71) Applicant: FUJIFILM Corporation, Tokyo (JP)

(72) Inventor: Yasuyuki SASADA, Kanagawa (JP)

(73) Assignee: FUJIFILM Corporation, Tokyo (JP)

(21) Appl. No.: 17/896,019

(22) Filed: Aug. 25, 2022

(30) Foreign Application Priority Data
Aug. 30, 2021 (JP) 2021-140220

(51) Int. Cl. C08J 5/18; C08J 3/20; C08K 9/08

(52) U.S. Cl. CPC C08J 5/18; C08J 3/203; C08K 9/08; C08J 2323/06; C08J 2327/12

(57) ABSTRACT

Provided are a polymer film including a particle A having a constricted structure and a polymer B; a laminate including the polymer film and a metal layer or metal wire disposed on at least one surface of the polymer film; and a method of producing the polymer film.

### CROSS-REFERENCE TO RELATED APPLICATIONS

This application claims priority under 35 USC 119 from Japanese Patent Application No. 2021-140220 filed on Aug. 30, 2021, the disclosure of which is incorporated by reference herein in their entirety.

### BACKGROUND OF THE INVENTION

### 1. Field of the Invention

The present disclosure relates to a polymer film and a method of producing the same, and a laminate.

### 2. Description of the Related Art

In recent years, the frequencies used in communication equipment tend to be extremely high. In order to suppress transmission loss in a high frequency band, insulating materials used in circuit boards are required to have a lowered relative dielectric constant and a lowered dielectric loss tangent.

As a thermoplastic resin composition of the related art, for example, a thermoplastic resin composition described in JP2020-105415A has been known.

JP2020-105415A describes a thermoplastic resin composition containing a random copolymer that has two or more monomer units having different glass transition temperatures and formed of homopolymers, in which the composition has a structure in which components with different elastic moduli are phase-separated on a nanoscale during mapping of the elastic moduli using an atomic force microscope (AFM) in a case of being formed into a molding plate.

### SUMMARY OF THE INVENTION

An object to be achieved by an aspect of the present invention is to provide a polymer film with improved brittleness and a method of producing the same.

Further, an object to be achieved by another aspect of the present invention is to provide a laminate formed of the polymer film.

The means for achieving the above-described object includes the following aspects.

<1> A polymer film comprising: a particle A having a constricted structure; and a polymer B.

<2> A polymer film comprising: a particle A; and a polymer B, in which in at least one cross section of the particle A, the particle A has one or more minimum values in a central portion excluding end portions of the particle A in terms of a length of the particle A in a direction perpendicular to a longitudinal direction.

<3> The polymer film according to <1> or <2>, in which a melting point Tm of the particle A is 400° C. or lower.

<4> The polymer film according to any one of <1> to <3>, in which a content of the particle A is 10% by volume or greater with respect to a total volume of the polymer film.

<5> The polymer film according to any one of <1> to <4>, in which the particle A is a particle formed by fusion welding of a plurality of particles or a particle formed by bonding a plurality of particles via a chemical bond on each particle surface.

<6> The polymer film according to <5>, in which the particle A is the particle formed by fusion welding of a plurality of particles.

<7> The polymer film according to any one of <1> to <6>, in which a dielectric loss tangent of the particle A is less than 0.01.

<8> The polymer film according to any one of <1> to <7>, in which the particle A contains at least one polymer selected from the group consisting of a fluoropolymer, a liquid crystal polymer, and polyethylene.

<9> The polymer film according to any one of <1> to <8>, in which a thermal expansion coefficient of the particle A is less than a thermal expansion coefficient of the polymer B.

<10> The polymer film according to any one of <1> to <9>, in which a tensile strength of the polymer B is 50 MPa or greater.

<11> The polymer film according to any one of <1> to <10>, in which the polymer B has at least one bond selected from the group consisting of a urethane bond, a urea bond, an amide bond, an ester bond, an ether bond, a N—C bond, a S—C bond, and a siloxane bond.

<12> The polymer film according to any one of <1> to <11>, further comprising: a polymerizable compound.

<13> The polymer film according to <12>, in which the polymerizable compound contains at least one group selected from the group consisting of a (meth)acryloyl group, an epoxy group, an oxetanyl group, an isocyanate group, an acid anhydride group, a carbodiimide group, a N-hydroxy ester group, a glyoxal group, an imide ester group, a halogenated alkyl group, a hydroxy group, a carboxy group, an amino group, an imidazole group, and a thiol group.

<14> The polymer film according to <12> or <13>, in which a content of the polymerizable compound is greater than 0% by mass and less than 5% by mass with respect to a total mass of the polymer film.

<15> A laminate comprising: the polymer film according to any one of <1> to <14>; and a metal layer or metal wire disposed on at least one surface of the polymer film.

<16> A method of producing a polymer film, comprising: a heating step of heating a polymer film precursor containing a particle to form a particle A having a constricted structure from the particle.

<17> A method of producing a polymer film, comprising: a heating step of heating a polymer film precursor containing a particle to form a particle A from the particle, in which in at least one cross section of the particle A, the particle A has one or more minimum values in a central portion excluding end portions of the particle A in terms of a length of the particle A in a direction perpendicular to a longitudinal direction.

<18> The method of producing a polymer film according to <16> or <17>, in which the polymer film precursor contains a polymerizable compound, and the method further includes a polymerizing step of polymerizing the polymerizable compound after the heating step.

<19> The method of producing a polymer film according to <18>, in which the polymer film obtained after the polymerizing step is contracted by 0.01% by volume or greater with respect to the polymer film precursor before the polymerizing step.

According to the aspect of the present invention, it is possible to provide a polymer film with improved brittleness and a method of producing the same.

Further, according to another aspect of the present invention, it is possible to provide a laminate formed of the polymer film.

### BRIEF DESCRIPTION OF THE DRAWINGS

FIG. 1 is a schematic cross-sectional view illustrating an example of a particle A having a constricted structure suitably used in the present disclosure.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

Further, in the present specification, a numerical range shown using “to” indicates a range including numerical values described before and after “to” as a lower limit and an upper limit.

In a numerical range described in a stepwise manner in the present disclosure, an upper limit or a lower limit described in one numerical range may be replaced with an upper limit or a lower limit in another numerical range described in a stepwise manner. Further, in a numerical range described in the present disclosure, an upper limit or a lower limit described in the numerical range may be replaced with a value described in an example.

Further, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, the concept of “(meth)acryl” includes both acryl and methacryl, and the concept of “(meth)acryloyl” includes both acryloyl and methacryloyl.

Further, the term “step” in the present specification indicates not only an independent step but also a step which cannot be clearly distinguished from other steps as long as the intended purpose of the step is achieved.

Further, in the present disclosure, “% by mass” has the same definition as that for “% by weight”, and “part by mass” has the same definition as that for “part by weight”.

Further, in the present disclosure, a combination of two or more preferred embodiments is a more preferred embodiment.

Further, the weight-average molecular weight (Mw) and the number average molecular weight (Mn) in the present disclosure are molecular weights converted using polystyrene as a standard substance by performing detection with a gel permeation chromatography (GPC) analyzer using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

Polymer Film

A polymer film according to a first embodiment of the present disclosure contains a particle A having a constricted structure and a polymer B.

A polymer film according to a second embodiment of the present disclosure contains a particle A and a polymer B, in which in at least one cross section of the particle, the particle A has one or more minimum values in a central portion excluding end portions of the particle in terms of a length of the particle in a direction perpendicular to a longitudinal direction.

In the present specification, the expression “polymer film according to the present disclosure” or “polymer film” simply denotes all the first embodiment and the second embodiment described above, unless otherwise specified. Further, the term “particle A” and the like simply denote the particle A and the like of both the first embodiment and the second embodiment described above, unless otherwise specified.

A polymer film containing particles of the related art has a problem that the brittleness is deteriorated.

Since the polymer film according to the present disclosure has a particle A having a constricted structure or a particle A in which, in at least one cross section of the particle, the particle has one or more minimum values in a central portion excluding end portions of the particle A in terms of the length of the particle in a direction perpendicular to the longitudinal direction, the polymer enters the structure in which the central portion of the particle A is narrowed, that is, the so-called constricted structure, and an anchor effect occurs, and thus a polymer film with improved brittleness by suppressing peeling due to the stress at the interface between the polymer and the particle A and suppressing concentration of the stress in voids generated in the peeled portion can be provided.

The brittleness can be evaluated, for example, based on breaking elongation. It can be determined that the brittleness is improved as the breaking elongation increases.

Particle A

The polymer film according to the first embodiment of the present disclosure contains a particle A having a constricted structure.

The polymer film according to the second embodiment of the present disclosure contains a particle A, in which in at least one cross section of the particle A, the particle A has one or more minimum values in a central portion excluding end portions of the particle A in terms of a length of the particle A in a direction perpendicular to a longitudinal direction.

It is preferable that the particle A of the polymer film according to the first embodiment of the present disclosure and the particle A of the polymer film according to the second embodiment of the present disclosure are particles having structures which are the same as or similar to each other and that the constricted structure is a structure in which in at least one cross section of the particle A, the particle A has one or more minimum values in a central portion excluding end portions of the particle A in terms of the length of the particle A in a direction perpendicular to the longitudinal direction.

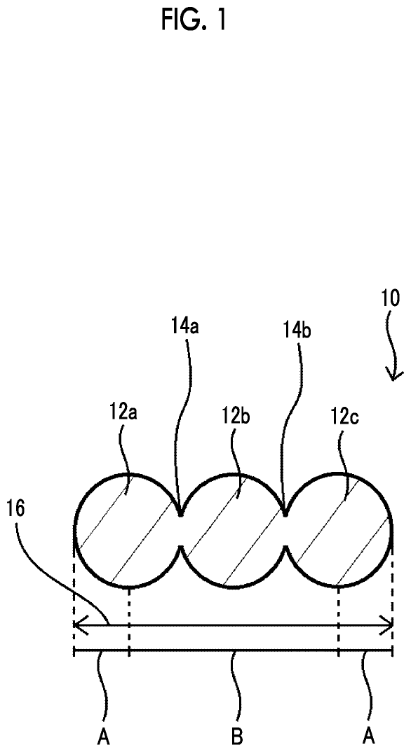

FIG. 1 is a schematic cross-sectional view illustrating an example of the particle A having a constricted structure suitably used in the present disclosure.

FIG. 1 is a schematic view illustrating a cross section of the particle A10 formed by fusion welding of three particles 12a, 12b, and 12c.

Regions A in the cross section of the particle 10 in FIG. 1 are end portions of the particle A, and a region B is a central portion of the particle A.

In the present disclosure, “end portions of the particle A” are portions in which the length of the particle A in a direction perpendicular to the longitudinal direction from the ends of the particle A is large, and “central portion of the particle A” is a portion other than the end portions of the particle A.

In the region B which is the central portion of the particle A, portions 14a and 14b in which the length of the particle A in a direction perpendicular to a longitudinal direction 16 is a minimum value are constricted structures.

That is, a particle A10 in FIG. 1 has two constricted structures and two minimum values described above.

The particle A may be an inorganic particle or an organic particle, but is preferably an organic resin particle.

Suitable examples of a method of producing the particle A in a case where the particle A is an organic particle and preferably an organic resin particle include a method of performing fusion welding on particles and a method of bonding particles via a chemical bond on each surface, and more suitable examples thereof include a method of performing fusion welding on particles.

In a case where the particle A is an inorganic particle, suitable examples of the method of producing the particle A include a method of bonding particles via a chemical bond on each surface.

Further, from the viewpoint of improving the brittleness, the particle A is preferably a particle formed by fusion welding of a plurality of particles or a particle formed by bonding a plurality of particles via a chemical bond on the particle surface and more preferably a particle formed by fusion welding of a plurality of particles.

Further, as a group forming the chemical bond, at least one selected from the group consisting of a group capable of covalent bonding, a group capable of ionic bonding, a group capable of hydrogen bonding, and a group capable of dipole interaction is preferable, and a group capable of covalent bonding is more preferable from the viewpoint of the strength of the bonded portion in the particle A.

The group capable of covalent bonding is appropriately selected depending on the kind of group present on the surface of the particle to be used.

The group capable of covalent bonding is not particularly limited as long as the group is capable of forming a covalent bond, and examples thereof include an epoxy group, an oxetanyl group, an isocyanate group, an acid anhydride group, a carbodiimide group, a N-hydroxy ester group, a glyoxal group, an imide ester group, a halogenated alkyl group, a thiol group, a hydroxy group, a carboxy group, an amino group, an amide group, an aldehyde group, and a sulfonic acid group. Among these, from the viewpoint of the adhesiveness to a metal foil or metal wire, it is preferable that the group is at least one functional group selected from the group consisting of an epoxy group, an oxetanyl group, an isocyanate group, an acid anhydride group, a carbodiimide group, a N-hydroxy ester group, a glyoxal group, an imide ester group, a halogenated alkyl group, and a thiol group.

In a case where one group capable of covalent bonding is a carboxy group, examples of the group capable of covalent bonding to the carboxy group include a hydroxy group and an epoxy group.

Further, in a case where one group capable of covalent bonding is a hydroxy group or —NH₂ (primary amino group), examples of the group capable of covalent bonding to the hydroxy group or —NH₂ include an isocyanate group and an epoxy group.

Among these, from the viewpoint of the strength of the bonded portion in the particle A, it is preferable to have an isocyanate group or an epoxy group on the particle surface, and an epoxy group is particularly preferable as the group capable of covalent bonding. Further, the isocyanate group can generate an amino group by thermal decomposition, and the epoxy group can also generate hydroxy group by thermal decomposition.

In a case where the particle A is an inorganic particle, examples of the material of the particle A include BN, Al₂O₃, AlN, TiO₂, SiO₂, barium titanate, strontium titanate, aluminum hydroxide, calcium carbonate, and a material containing two or more of these.

Further, in a case where the particle A is an organic particle, as the material of the particle A, a polymer is preferable, and a thermoplastic resin is more preferable.

Among these, the particle A is preferably a particle containing at least one polymer selected from the group consisting of a fluoropolymer, a liquid crystal polymer, and polyethylene from the viewpoints of the dielectric loss tangent of the film and improving the brittleness of the film, more preferably a liquid crystal polymer from the viewpoint of the dielectric loss tangent of the film, and still more preferably a fluoropolymer from the viewpoints of the heat resistance and the mechanical strength.

Further, it is preferable that the polymer is a polymer having a dielectric loss tangent of 0.01 or less.

In the present disclosure, the kind of polymer used in the particle A is not particularly limited, and a known polymer can be used.

Examples of the polymer include thermoplastic resins such as a liquid crystal polymer, a fluoropolymer, a polymerized substance of a compound containing a cyclic aliphatic hydrocarbon group and an ethylenically unsaturated group, polyether ether ketone, polyolefin, polyamide, polyester, polyphenylene sulfide, polyether ketone, polycarbonate, polyethersulfone, polyphenylene ether and a modified product thereof, and polyetherimide, elastomers such as a copolymer of glycidyl methacrylate and polyethylene, and thermosetting resins such as a phenol resin, an epoxy resin, a polyimide resin, and a cyanate resin.

Liquid Crystal Polymer

From the viewpoint of the dielectric loss tangent of the film, it is preferable that the polymer used in the particle A is a liquid crystal polymer.

The kind of the liquid crystal polymer is not particularly limited, and a known liquid crystal polymer can be used.

Further, the liquid crystal polymer may be a thermotropic liquid crystal polymer that exhibits liquid crystallinity in a melting state or may be a lyotropic liquid crystal polymer that exhibits liquid crystallinity in a solution state. Further, in a case of the thermotropic liquid crystal polymer, it is preferable that the polymer is melted at a temperature of 450° C. or lower.

Examples of the liquid crystal polymer include liquid crystal polyester, liquid crystal polyester amide in which an amide bond is introduced into liquid crystal polyester, liquid crystal polyester ether in which an ether bond is introduced into liquid crystal polyester, and liquid crystal polyester carbonate in which a carbonate bond is introduced into liquid crystal polyester.

Further, from the viewpoint of the liquid crystallinity and the linear expansion coefficient, a polymer having an aromatic ring is preferable, and aromatic polyester or aromatic polyester amide is more preferable as the liquid crystal polymer.

Further, the liquid crystal polymer may be a polymer in which an imide bond, a carbodiimide bond, a bond derived from an isocyanate such as an isocyanurate bond, or the like is further introduced into aromatic polyester or aromatic polyester amide.

Further, it is preferable that the liquid crystal polymer is a wholly aromatic liquid crystal polymer formed of only an aromatic compound as a raw material monomer.

Examples of the liquid crystal polymer include

1) a liquid crystal polymer obtained by polycondensing an aromatic hydroxycarboxylic acid (i), an aromatic dicarboxylic acid (ii), and at least one compound (iii) selected from the group consisting of an aromatic diol, an aromatic hydroxyamine and an aromatic diamine,

2) a liquid crystal polymer obtained by polycondensing a plurality of kinds of aromatic hydroxycarboxylic acids,

3) a liquid crystal polymer obtained by polycondensing an aromatic dicarboxylic acid (i) and at least one compound (ii) selected from the group consisting of an aromatic diol, an aromatic hydroxyamine, and an aromatic diamine, and

4) a liquid crystal polymer obtained by polycondensing polyester (i) such as polyethylene terephthalate and an aromatic hydroxycarboxylic acid (ii).

Here, as a part or the entirety of the aromatic hydroxycarboxylic acid, the aromatic dicarboxylic acid, the aromatic diol, the aromatic hydroxyamine, and the aromatic diamine, each independently, a derivative that can be polycondensed may be used.

Examples of the polymerizable derivative of a compound containing a carboxy group, such as an aromatic hydroxycarboxylic acid or an aromatic dicarboxylic acid, include a derivative (ester) obtained by converting a carboxy group to an alkoxycarbonyl group or an aryloxycarbonyl group, a derivative (acid halide) obtained by converting a carboxy group to a haloformyl group, and a derivative (acid anhydride) obtained by converting a carboxy group to an acyloxycarbonyl group.

Examples of the polymerizable derivative of a compound containing a hydroxy group, such as an aromatic hydroxycarboxylic acid, an aromatic diol, or an aromatic hydroxyamine, include a derivative (acylated product) obtained by acylating a hydroxy group and converting the acylated group to an acyloxy group.

Examples of the polymerizable derivative of a compound containing an amino group, such as an aromatic hydroxyamine or an aromatic diamine, include a derivative (acylated product) obtained by acylating an amino group and converting the acylated group to an acylamino group.

From the viewpoints of the liquid crystallinity, the dielectric loss tangent of the film, and the adhesiveness to the metal foil or the metal wire, the liquid crystal polymer has preferably a constitutional repeating unit represented by any of Formulae (1) to (3) (hereinafter, the constitutional repeating unit and the like represented by Formula (1) will also be referred to as the repeating unit (1) and the like), more preferably a constitutional repeating unit represented by Formula (1), and particularly preferably a constitutional repeating unit represented by Formula (1), a constitutional repeating unit represented by Formula (2), and a constitutional repeating unit represented by Formula (3).

—O—Ar¹—CO— Formula (1)

—CO—Ar²—CO— Formula (2)

—X—Ar³—Y— Formula (3)

In Formulae (1) to (3), Ar¹ represents a phenylene group, a naphthylene group, or a biphenylylene group, Ar² and Ar³ each independently represent a phenylene group, a naphthylene group, a biphenylylene group, or a group represented by Formula (4), X and Y each independently represent an oxygen atom or an imino group, and hydrogen atoms in the groups represented by Ar¹ to Ar³ may be each independently substituted with a halogen atom, an alkyl group, or an aryl group.

—Ar⁴—Z—Ar⁵— Formula (4)

In Formula (4), Ar⁴ and Ar⁵ each independently represent a phenylene group or a naphthylene group, and Z represents an oxygen atom, a sulfur atom, a carbonyl group, a sulfonyl group, or an alkylene group.

Examples of the halogen atom of include a fluorine atom, a chlorine atom, a bromine atom, and an iodine atom.

Examples of the alkyl group include a methyl group, an ethyl group, an n-propyl group, an isopropyl group, an n-butyl group, an isobutyl group, an s-butyl group, a t-butyl group, an n-hexyl group, a 2-ethylhexyl group, an n-octyl group, and an n-decyl group, and the number of carbon atoms thereof is preferably in a range of 1 to 10.

Examples of the aryl group include a phenyl group, an o-tolyl group, an m-tolyl group, a p-tolyl group, a 1-naphthyl group, and a 2-naphthyl group, and the number of carbon atoms is preferably in a range of 6 to 20.

In a case where the hydrogen atom is substituted with any of these groups, the number thereof is preferably 2 or less and more preferably 1 for each group independently represented by Ar¹, Ar², or Ar³.

Examples of the alkylene group include a methylene group, a 1,1-ethanediyl group, a 1-methyl-1,1-ethanediyl group, a 1,1-butanediyl group, and a 2-ethyl-1,1-hexanediyl group, and the number of carbon atoms thereof is preferably in a range of 1 to 10.

The repeating unit (1) is a constitutional repeating unit derived from a predetermined aromatic hydroxycarboxylic acid.

Preferred examples of the repeating unit (1) include a constitutional repeating unit in which Ar¹ represents a p-phenylene group (constitutional repeating unit derived from p-hydroxybenzoic acid), a constitutional repeating unit in which Ar¹ represents a 2,6-naphthylene group (constitutional repeating unit derived from 6-hydroxy-2-naphthoic acid), and a constitutional repeating unit in which Ar¹ represents a 4,4′-biphenylylene group (constitutional repeating unit derived from 4′-hydroxy-4-biphenylcarboxylic acid).

The repeating unit (2) is a constitutional repeating unit derived from a predetermined aromatic dicarboxylic acid.

Preferred examples of the repeating unit (2) include a constitutional repeating unit in which Ar² represents a p-phenylene group (constitutional repeating unit derived from terephthalic acid), a constitutional repeating unit in which Ar² represents an m-phenylene group (constitutional repeating unit derived from isophthalic acid), a constitutional repeating unit in which Ar² represents a 2,6-naphthylene group (constitutional repeating unit derived from 2,6-naphthalenedicarboxylic acid), and a constitutional repeating unit in which Ar² represents a diphenylether-4,4′-diyl group (constitutional repeating unit derived from diphenylether-4,4′-dicarboxylic acid).

The repeating unit (3) is a constitutional repeating unit derived from a predetermined aromatic diol, an aromatic hydroxylamine, or an aromatic diamine.

Preferred examples of the repeating unit (3) include a constitutional repeating unit in which Ar³ represents a p-phenylene group (constitutional repeating unit derived from hydroquinone, p-aminophenol, or p-phenylenediamine), a constitutional repeating unit in which Ar³ represents an m-phenylene group (constitutional repeating unit derived from isophthalic acid), and a constitutional repeating unit in which Ar³ represents a 4,4′-biphenylylene group (constitutional repeating unit derived from 4,4′-dihydroxybiphenyl, 4-amino-4′-hydroxybiphenyl, or 4,4′-diaminobiphenyl).

The content of the repeating unit (1) is preferably 30% by mole or greater, more preferably in a range of 30% by mole to 80% by mole, still more preferably in a range of 30% by mole to 60% by mole, and particularly preferably in a range of 30% by mole to 40% by mole with respect to the total amount of all constitutional repeating units (value obtained by dividing the mass of each constitutional repeating unit constituting the liquid crystal polymer by the formula weight of each repeating unit to acquire the amount (mole) equivalent to the substance amount of each repeating unit and adding up the acquired values).

The content of the repeating unit (2) is preferably 35% by mole or less, more preferably in a range of 10% by mole to 35% by mole, still more preferably in a range of 20% by mole to 35% by mole, and particularly preferably in a range of 30% by mole to 35% by mole with respect to the total amount of all constitutional repeating units.

The content of the repeating unit (3) is preferably 35% by mole or less, more preferably in a range of 10% by mole to 35% by mole, still more preferably in a range of 20% by mole to 35% by mole, and particularly preferably in a range of 30% by mole to 35% by mole with respect to the total amount of all constitutional repeating units.

The heat resistance, the strength, and the rigidity are likely to be improved as the content of the repeating unit (1) increases, but the solubility in a solvent is likely to be decreased in a case where the content thereof is extremely large.

The ratio of the content of the repeating unit (2) to the content of the repeating unit (3) is expressed as [content of repeating unit (2)]/[content of repeating unit (3)] (mol/mol), and preferably in a range of 0.9/1 to 1/0.9, more preferably in a range of 0.95/1 to 1/0.95, and still more preferably in a range of 0.98/1 to 1/0.98.

The liquid crystal polymer may have two or more kinds of each of the repeating units (1) to (3) independently. Further, the liquid crystal polymer may have a constitutional repeating unit other than the repeating units (1) to (3), but the content thereof is preferably 10% by mole or less and more preferably 5% by mole or less with respect to the total amount of all the repeating units.

The liquid crystal polymer has preferably a repeating unit in which at least one of X or Y represents an imino group, that is, at least one of a constitutional repeating unit derived from a predetermined aromatic hydroxylamine or a constitutional repeating unit derived from an aromatic diamine as the repeating unit (3) from the viewpoint of excellent solubility in a solvent and more preferably only a repeating unit in which at least one of X or Y represents an imino group as the repeating unit (3).

It is preferable that the liquid crystal polymer is produced by melt-polymerizing raw material monomers corresponding to the constitutional repeating units constituting the liquid crystal polymer. The melt polymerization may be carried out in the presence of a catalyst, and examples of the catalyst include metal compounds such as magnesium acetate, stannous acetate, tetrabutyl titanate, lead acetate, sodium acetate, potassium acetate, and antimony trioxide, and nitrogen-containing heterocyclic compounds such as 4-(dimethylamino)pyridine and 1-methylimidazole. Among these, the nitrogen-containing heterocyclic compounds are preferably used. The melt polymerization may be further carried out by solid phase polymerization as necessary.

The flow start temperature of the liquid crystal polymer is preferably 250° C. or higher, more preferably 250° C. or higher and 350° C. or lower, and still more preferably 260° C. or higher and 330° C. or lower. In a case where the flow start temperature of the liquid crystal polymer is in the above-described range, the solubility, the heat resistance, the strength, and the rigidity are excellent, and the viscosity of the solution is appropriate.

The flow start temperature, also referred to as a flow temperature, is a temperature at which a viscosity of 4,800 Pas (48,000 poises) is exhibited in a case where the liquid crystal polymer is melted and extruded from a nozzle having an inner diameter of 1 mm and a length of 10 mm while the temperature is raised at a rate of 4° C./min under a load of 9.8 MPa (100 kg/cm²) using a capillary rheometer and is a guideline for the molecular weight of liquid crystal polyester (“Liquid Crystal Polymers-Synthesis/Molding/Applications-”, written by Naoyuki Koide, CMC Corporation, Jun. 5, 1987, see p. 95).

Further, the weight-average molecular weight of the liquid crystal polymer is preferably 1,000,000 or less, more preferably 3,000 to 300,000, still more preferably in a range of 5,000 to 100,000, and particularly preferably in a range of 5,000 to 30,000. In a case where the weight-average molecular weight of the liquid crystal polymer is in the above-described range, the film after heat treatment is excellent in thermal conductivity, heat resistance, strength, and rigidity in the thickness direction.

Fluoropolymer

From the viewpoints of the heat resistance and the mechanical strength, a fluoropolymer is preferable as the polymer used in the particle A.

The fluoropolymer used in the present disclosure is not particularly limited, and a known fluoropolymer can be used.

Examples of the fluoropolymer include polytetrafluoroethylene, polychlorotrifluoroethylene, polyvinylidene fluoride, polyvinyl fluoride, a perfluoroalkoxy fluororesin, an ethylene tetrafluoride/propylene hexafluoride copolymer, an ethylene/ethylene tetrafluoride copolymer, and an ethylene/chlorotrifluoroethylene copolymer.

Among these, polytetrafluoroethylene is preferable.

Polyolefin

It is preferable that the polymer used in the particle A contains polyolefin.

The polyolefin is not particularly limited, but from the viewpoint of improving the brittleness, poly-α-olefin is preferable, polyethylene or polypropylene is more preferable, and polyethylene is particularly preferable.

The weight-average molecular weight Mw of the polymer used in the particle A is preferably 1,000 or greater, more preferably 2,000 or greater, and particularly preferably 5,000 or greater. Further, the weight-average molecular weight Mw of the polymer having a dielectric loss tangent of 0.01 or less is preferably 1,000,000 or less, more preferably 300,000 or less, and particularly preferably less than 100,000.

From the viewpoint of improving the brittleness, the melting point Tm of the particle A is preferably 400° C. or lower, more preferably 350° C. or lower, and particularly preferably 320° C. or lower. Further, from the viewpoints of the dielectric loss tangent of the polymer film, the adhesiveness to the metal foil or the metal wire, and the heat resistance, the lower limit of the melting point Tm of the particle A is preferably 200° C. or higher, more preferably 230° C. or higher, still more preferably 260° C. or higher, and particularly preferably 280° C. or higher.

Further, the melting point Tm of the particle A is preferably lower than the melting point Tm of the polymer B, more preferably lower by 10° C. or higher, still more preferably lower by 20° C. or higher, and particularly preferably lower by 30° C. or higher.

The melting point Tm in the present disclosure is defined as a value measured by a differential scanning calorimetry (DSC) device.

From the viewpoints of the dielectric loss tangent of the polymer film and improving the brittleness, the dielectric loss tangent of the particle A is preferably less than 0.01, more preferably 0.008 or less, still more preferably 0.005 or less, and particularly preferably greater than 0 and 0.004 or less.

The method of measuring the dielectric loss tangent of the polymer film, the particle, or the polymer in the present disclosure is as follows.

The dielectric loss tangent is measured by the resonance perturbation method at a frequency of 10 GHz. A 10 GHz cavity resonator (CP531, manufactured by EM labs, Inc.) is connected to a network analyzer (“E8363B”, manufactured by Agilent Technology), and a sample of a film or a polymer (width: 2.0 mm×length: 80 mm) is inserted into the cavity resonator, and the dielectric loss tangent of the film is measured based on a change in resonance frequency for 96 hours before and after the insertion in an environment of a temperature of 25° C. and a humidity 60% RH. Further, in a case where the laminate has a metal foil or a metal wire, the metal foil or the metal wire is removed by ferric chloride before the measurement.

Further, the dielectric loss tangent of the particle A is measured by the above-described method after preparing a green compact sample (width: 2.0 mm×length: 80 mm) by compression molding.

From the viewpoint of improving the brittleness, the thermal expansion coefficient of the particle A is preferably less than the thermal expansion coefficient of the polymer B.

From the viewpoint of improving the brittleness, the thermal expansion coefficient of the particle A is preferably in a range of −30 ppm/K to 40 ppm/K, more preferably in a range of −20 ppm/K to 35 ppm/K, still more preferably in a range of −10 ppm/K to 30 ppm/K, and particularly preferably in a range of 0 ppm/K to 25 ppm/K.

The thermal expansion coefficient in the present disclosure is measured by the following method.

The thermal expansion coefficient is calculated from the inclination of the TMA curve between 30° C. and 150° C. using a thermomechanical analyzer (TMA) in a case where a tensile load of 1 g is applied to both ends of a polymer film or a sample of a polymer having a width of 5 mm and a length of 20 mm, the polymer film or the sample is heated from 25° C. to 200° C. at a rate of 5° C./min, cooled to 30° C. at a rate of 20° C./min, and heated again at a rate of 5° C./min.

Further, the thermal expansion coefficient of the particle A is measured by the above-described method after preparing a green compact sample (width: 5 mm, length: 20 mm) by compression molding.

From the viewpoints of the linear expansion coefficient and the adhesiveness to the metal foil, the average maximum length of the particle A is preferably in a range of 20 nm to 5 μm, more preferably in a range of 30 nm to 2 μm, still more preferably in a range of 50 nm to 1 μm, and particularly preferably in a range of 50 nm to 500 nm.

The polymer film may contain only one or two or more kinds of particles A, and the particles may be particles formed by fusion welding of particles formed of different materials.

From the viewpoint of improving the brittleness, the content of the particle A in the polymer film according to the present disclosure is preferably 5% by volume or greater, more preferably 10% by volume or greater, still more preferably in a range of 15% by volume to 80% by volume, and particularly preferably in a range of 20% by volume to 75% by volume with respect to the total volume of the polymer film.

Polymer B

The polymer film according to the present disclosure contains the polymer B.

It is preferable that the polymer film contains a polymer having a dielectric loss tangent of 0.01 or less as the polymer B.

From the viewpoints of the dielectric loss tangent of the polymer film and the adhesiveness to the metal foil or the metal wire, the dielectric loss tangent of the polymer B is preferably 0.005 or less, more preferably 0.004 or less, and particularly preferably greater than 0 and 0.003 or less.

The weight-average molecular weight Mw of the polymer B is preferably 1,000 or greater, more preferably 2,000 or greater, and particularly preferably 5,000 or greater. Further, the weight-average molecular weight Mw of the polymer having a dielectric loss tangent of 0.005 or less is preferably 1,000,000 or less, more preferably 300,000 or less, and particularly preferably less than 100,000.

From the viewpoints of the dielectric loss tangent of the polymer film, the adhesiveness to the metal foil or the metal wire, and the heat resistance, the melting point Tm of the polymer B is preferably 200° C. or higher, more preferably 250° C. or higher, still more preferably 280° C. or higher, and particularly preferably 300° C. or higher and 420° C. or lower.

From the viewpoints of the dielectric loss tangent of the polymer film, the adhesiveness to the metal foil or the metal wire, and the heat resistance, the glass transition temperature Tg of the polymer B is preferably 150° C. or higher, more preferably 200° C. or higher, and particularly preferably 200° C. or higher and lower than 280° C.

The glass transition temperature Tg in the present disclosure is defined as a value measured by a differential scanning calorimetry (DSC) device.

In the present disclosure, the kind of the polymer B is not particularly limited, and a known polymer can be used.

Examples of the polymer B include thermoplastic resins such as a liquid crystal polymer, a fluoropolymer, a polymerized substance of a compound containing a cyclic aliphatic hydrocarbon group and a group having an ethylenically unsaturated bond, polyether ether ketone, polyolefin, polyamide, polyester, polyphenylene sulfide, polyether ketone, polycarbonate, polyethersulfone, polyphenylene ether and a modified product thereof, and polyetherimide, elastomers such as a copolymer of glycidyl methacrylate and polyethylene, and thermosetting resins such as a phenol resin, an epoxy resin, a polyimide resin, and a cyanate resin.

Among these, at least one polymer selected from the group consisting of a liquid crystal polymer, a fluoropolymer, a polymerized substance of a compound containing a cyclic aliphatic hydrocarbon group and an ethylenically unsaturated group, and polyether ether ketone is preferable from the viewpoints of the dielectric loss tangent of the polymer film, the adhesiveness to the metal foil or the metal wire, and the heat resistance, at least one polymer selected from the group consisting of a liquid crystal polymer and a fluoropolymer is more preferable, a liquid crystal polymer is particularly preferable from the viewpoint of the dielectric loss tangent of the polymer film, and a fluoropolymer is most preferable from the viewpoints of the heat resistance and the mechanical strength.

The preferable aspects of the liquid crystal polymer and the fluoropolymer used in the polymer B are the same as the preferable aspects of the liquid crystal polymer and the fluoropolymer described in the particle A.

From the viewpoint of improving the strength and the brittleness, it is preferable that the polymer B has a crosslinked structure.

Further, from the viewpoint of improving the strength and the brittleness, the polymer B has preferably at least one bond selected from the group consisting of a urethane bond, a urea bond, an amide bond, an ester bond, an ether bond, a C—C bond, a N—C bond, a S—C bond, and a siloxane bond, more preferably at least one bond selected from the group consisting of a urethane bond, a urea bond, an amide bond, an ester bond, an ether bond, a N—C bond, a S—C bond, and a siloxane bond, and particularly preferably a N—C bond.

Further, the weight-average molecular weight of the polymer B is preferably 1,000,000 or less, more preferably in a range of 3,000 to 300,000, still more preferably in a range of 5,000 to 100,000, and particularly preferably in a range of 5,000 to 30,000.

In a case where the weight-average molecular weight of the polymer B is in the above-described range, the film after heat treatment is excellent in thermal conductivity, heat resistance, strength, and rigidity in the thickness direction.

The tensile strength of the polymer B is preferably 50 MPa or greater from the viewpoint of improving the brittleness.

As a method of measuring the tensile strength in the present disclosure, a sample with a size of 10 mm×200 mm which is obtained by cutting out the polymer film is humidity-controlled at 23° C. and a relative humidity of 60% for 2 hours, and the maximum stress until breakage at an initial sample length of 100 mm and a tensile rate of 10 mm/min is acquired using a tensilon tensile tester (RTA-100, manufactured by Orientec Co., Ltd.) and defined as the tensile strength.

It is preferable that the polymer B is a polymer that is soluble in a specific organic solvent (hereinafter, also referred to as “soluble polymer”).

Specifically, the soluble polymer in the present disclosure is a polymer in which 0.1 g or greater thereof is dissolved at 25° C. in 100 g of at least one solvent selected from the group consisting of N-methylpyrrolidone, N-ethylpyrrolidone, dichloromethane, dichloroethane, chloroform, N,N-dimethylacetamide, γ-butyrolactone, dimethylformamide, ethylene glycol monobutyl ether, and ethylene glycol monoethyl ether.

The polymer film according to the present disclosure may contain only one or two or more kinds of the polymers B.

From the viewpoint of improving the brittleness, the content of the polymer B in the polymer film according to the present disclosure is preferably in a range of 20% by volume to 95% by volume, more preferably in a range of 20% by volume to 80% by volume, still more preferably in a range of 20% by volume to 70% by volume, and particularly preferably in a range of 25% by volume to 65% by volume with respect to the total volume of the polymer film.

Polymerizable Compound

From the viewpoint of improving the brittleness, it is preferable that the polymer film according to the present disclosure further contains a polymerizable compound.

It is preferable that the polymerizable compound is an unpolymerized polymerizable compound formed by polymerizing at least a part of the polymer B.

The polymerizable compound is not particularly limited, and a known polymerizable compound can be used.

Further, the polymerizable compound contains preferably at least one group selected from the group consisting of a (meth)acryloyl group, an epoxy group, an oxetanyl group, an isocyanate group, an acid anhydride group, a carbodiimide group, a N-hydroxy ester group, a glyoxal group, an imide ester group, a halogenated alkyl group, a hydroxy group, a carboxy group, an amino group, an imidazole group, and a thiol group and more preferably a (meth)acryloyl group.

Further, an ethylenically unsaturated compound is preferable as the polymerizable compound.

The polymerizable compound may be a low-molecular-weight compound having a molecular weight of less than 1,000 or a polymer compound having a weight-average molecular weight Mw of 1,000 or greater.

The polymer film according to the present disclosure may contain only one or two or more kinds of the polymerizable compounds.

From the viewpoint of improving the brittleness, the content of the polymerizable compound in the polymer film according to the present disclosure is preferably greater than 0% by mass and less than 5% by mass and more preferably greater than 0% by mass and less than 3% by mass with respect to the total mass of the polymer film.

Other Additives

The polymer film according to the present disclosure may contain other additives.

Known additives can be used as other additives. Specific examples of other additives include a leveling agent, an antifoaming agent, an antioxidant, an ultraviolet absorbing agent, a flame retardant, and a colorant.

The total content of the other additives is preferably 25 parts by mass or less, more preferably 10 parts by mass or less, and still more preferably 5 parts by mass or less with respect to 100 parts by mass of the content of the polymer B.

Dielectric Loss Tangent

From the viewpoint of suppressing breakage failure during peeling and reducing the transmission loss of the prepared substrate, the dielectric loss tangent of the polymer film according to the present disclosure is preferably 0.01 or less, more preferably 0.005 or less, still more preferably 0.004 or less, and particularly preferably greater than 0 and 0.003 or less.

Thermal Expansion Coefficient

From the viewpoint of thermal stability, the thermal expansion coefficient of the polymer film according to the present disclosure is preferably in a range of −20 ppm/K to 50 ppm/K, more preferably in a range of −10 ppm/K to 40 ppm/K, still more preferably in a range of 0 ppm/K to 35 ppm/K, and particularly preferably in a range of 10 ppm/K to 30 ppm/K.

The thermal expansion coefficient in the present disclosure is measured by the following method.

A tensile load of 1 g is applied to both ends of a film having a width of 5 mm and a length of 20 mm, and the thermal expansion coefficient is calculated from the inclination of the TMA curve between 30° C. and 150° C. using a thermomechanical analyzer (TMA) in a case where the temperature is raised from 25° C. to 200° C. at a rate of 5° C./min, lowered to 30° C. at a rate of 2° C./min, and raised again at a rate of 5° C./min. Further, in a case where the laminate has a metal foil or a metal wire, the metal foil or the metal wire is removed by ferric chloride before the measurement.

The polymer film according to the present disclosure may have a monolayer structure or a multilayer structure.

For example, the polymer film according to the present disclosure may have a structure having a layer A that contains the particle A and the polymer B and a layer B provided on at least one surface of the layer A or a structure having a layer B, a layer A that contains the particle A and the polymer B, and a layer C in this order.

Further, it is preferable that the layer B and the layer C each independently contain a liquid crystal polymer.

The average thickness of the layer A is not particularly limited, but from the viewpoints of the dielectric loss tangent of the polymer film and the adhesiveness to the metal foil or the metal wire, the average thickness thereof is preferably in a range of 5 μm to 90 μm, more preferably in a range of 10 μm to 70 μm, and particularly preferably in a range of 15 μm to 50 μm.

The method of measuring the average thickness of each layer in the polymer film according to the present disclosure is measured in the following manner.

The thickness of each layer is evaluated by cutting the polymer film with a microtome and observing the cross section with an optical microscope. Three or more sites of the cross-sectional sample are cut out, the thickness is measured at three or more points in each cross section, and the average value thereof is defined as the average thickness.

From the viewpoints of the dielectric loss tangent of the polymer film and the adhesiveness to the metal foil or the metal wire, it is preferable that the average thicknesses of the layer B and the layer C are each independently less than the average thickness of the layer A.

From the viewpoints of the dielectric loss tangent of the polymer film and the adhesiveness to the metal foil or the metal wire, the value of T^{A}/T^{B}, which is the ratio of an average thickness T^{A} of the layer A to an average thickness T^{B} of the layer B, is preferably greater than 1, more preferably in a range of 2 to 100, still more preferably in a range of 2.5 to 20, and particularly preferably in a range of 3 to 10.

From the viewpoints of the dielectric loss tangent of the polymer film and the adhesiveness to the metal foil or the metal wire, the value of T^{A}/T^{C}, which is the ratio of the average thickness T^{A} of the layer A to an average thickness T^{C} of the layer C, is preferably greater than 1, more preferably in a range of 2 to 100, still more preferably in a range of 2.5 to 20, and particularly preferably in a range of 3 to 10.

Further, from the viewpoints of the linear expansion coefficient and the adhesiveness to the metal foil or the metal wire, the value of T^{C}/T^{B}, which is the ratio of the average thickness T^{C} of the layer C to the average thickness T^{B} of the layer B, is preferably in a range of 0.2 to 5, more preferably in a range of 0.5 to 2, and particularly preferably in a range of 0.8 to 1.2.

Further, from the viewpoints of the dielectric loss tangent of the polymer film and the adhesiveness to the metal foil or the metal wire, the average thicknesses of the layer B and the layer C are each independently preferably in a range of 0.1 μm to 20 μm, more preferably in a range of 0.5 μm to 15 μm, still more preferably in a range of 1 μm to 10 μm, and particularly preferably in a range of 3 μm to 8 μm.

From the viewpoints of the strength, the thermal expansion coefficient, and the adhesiveness to the metal foil or the metal wire, the average thickness of the polymer film according to the present disclosure is preferably in a range of 6 μm to 200 μm, more preferably in a range of 12 μm to 100 μm, and particularly preferably in a range of 20 μm to 60 μm.

The average thickness of the polymer film is measured at optional five sites using an adhesive film thickness meter, for example, an electronic micrometer (product name, “KG3001A”, manufactured by Anritsu Corporation), and the average value of the measured values is defined as the average thickness of the polymer film.

Applications

The polymer film according to the present disclosure can be used for various applications. Among the various applications, the polymer film can be used suitably as a film for an electronic component such as a printed wiring board and more suitably for a flexible printed circuit board.

Further, the polymer film according to the present disclosure can be suitably used as a metal adhesive film.

Method of Producing Polymer Film

A method of producing the polymer film according to the first embodiment of the present disclosure includes a heating step of heating a polymer film precursor containing a particle to form a particle A having a constricted structure from the particle.

A method of producing the polymer film according to the second embodiment of the present disclosure includes a heating step of heating a polymer film precursor containing a particle to form a particle A from the particle, in which in at least one cross section of the particle A, the particle A has one or more minimum values in a central portion excluding end portions of the particle A in terms of the length of the particle A in a direction perpendicular to the longitudinal direction.

In the present specification, the expression “method of producing the polymer film according to the present disclosure” or “method of producing the polymer film” simply denotes both the first embodiment and the second embodiment described above, unless otherwise specified. Further, the term “heating step” and the like simply denote the heating step and the like of both the first embodiment and the second embodiment described above, unless otherwise specified.

It is preferable that the polymer film according to the present disclosure is a film produced by the method of producing the polymer film according to the present disclosure.

In the method of producing the polymer film according to the present disclosure, the preferable aspects of the above-described components among the components to be used, each component contained in the film to be obtained, and the content of each component are the same as the preferable aspects in the polymer film according to the present disclosure.

Further, in the method of producing the polymer film according to the present disclosure, the amount of each component to be used is the same as the preferable amount corresponding to the preferable aspect of the content of each component in the polymer film according to the present disclosure.

In the method of producing the polymer film according to the present disclosure, each preferable physical property value of the produced film is the same as the preferable aspect in the polymer film according to the present disclosure.

Heating Step

The method of producing the polymer film according to the first embodiment of the present disclosure includes a heating step of heating a polymer film precursor containing a particle to form a particle A from the particle.

The preferable aspect of the material of the particle contained in the polymer film precursor is the same as the preferable aspect of the material of the particle A described above.

Further, it is preferable that the particle contained in the polymer film precursor contain a polymer.

Further, it is preferable that the polymer film precursor contains a polymer B or a polymerizable compound forming the polymer B.

As the polymer B and the polymerizable compound in the polymer film precursor, those described above in the polymer film are preferable.

In a case where the particle is an inorganic particle, from the viewpoint of improving the brittleness, the average particle diameter of the inorganic particles is preferably in a range of 5 nm to 2 μm, more preferably in a range of 10 nm to 1 μm, still more preferably in a range of 20 nm to 1 μm, and particularly preferably in a range of 25 nm to 500 nm.

In a case where the particle is an organic particle, from the viewpoint of improving the brittleness, the average particle diameter of the organic particles is preferably in a range of 5 nm to 2 μm, more preferably in a range of 10 nm to 1 μm, still more preferably in a range of 20 nm to 500 nm, and particularly preferably in a range of 25 nm to 90 nm.

The heating temperature in the heating step is not particularly limited as long as the particle A can be formed, but in a case where the particle contains a polymer, the heating temperature thereof is preferably the melting point Tm of the polymer−30° C. or higher and the melting point Tm of the polymer B or lower and more preferably the melting point Tm of the polymer−20° C. or higher and the melting point Tm of the polymer B−10° C. or lower.

Further, the heating temperature is preferably the melting point Tm of the polymer+40° C. or lower, more preferably the melting point Tm of the polymer+30° C. or lower, and particularly preferably the melting point Tm of the polymer+20° C. or lower.

The heating time in the heating step is not particularly limited and can be appropriately selected depending on the formation state of the particles A, and is, for example, preferably in a range of 0.1 minutes to 10 hours.

The heating temperature and the heating time can be appropriately changed depending on the kind of the particle B and the kind of the polymer, and can be lowered or shortened by another means such as addition of a catalyst.

In the method of producing the polymer film according to the present disclosure, the amount of dissolved oxygen is preferably 500 ppm or less and more preferably 300 ppm or less at the start of heating the film. In a case where the amount of dissolved oxygen is in the above-described range, a film having a lower dielectric loss tangent can be obtained.

Further, the start of heating denotes the time at which application of heat to the film is started.

It is presumed that crystallization of the polymer B (particularly in a case where the polymer B is a liquid crystal polymer) proceeds in the polymer film and the dielectric loss tangent of the polymer film can be decreased by performing the heating step.

In the present disclosure, the amount of dissolved oxygen is measured using a dissolved oxygen meter, for example, a portable oxygen analyzer “ORBISPHERE 3650” (manufactured by Hach Ultra Analytics Inc.).

The heating step may be performed in an inert gas atmosphere or in an oxygen-containing atmosphere. From the viewpoint of production efficiency, the heating step is performed preferably in an atmosphere with an oxygen concentration of 500 ppm or greater and more preferably in an air atmosphere.

Polymerizing Step

In the method of producing the polymer film according to the present disclosure, it is preferable that the polymer film precursor contains a polymerizable compound and that the method includes a polymerizing step of polymerizing the polymerizable compound after the heating step.

The content of the polymerizable compound in the polymer film precursor is preferably in a range of 10% by mass to 80% by mass and more preferably in a range of 20% by mass to 75% by mass with respect to the total mass of the polymer film precursor.

Further, in a case where the polymer film precursor contains a polymerizable compound, it is preferable that the polymer film precursor contains a polymerization initiator.

As the polymerization initiator, a known polymerization initiator can be used, and examples thereof include a photopolymerization initiator and a thermal polymerization initiator. Further, the polymerization initiator may be a radical polymerization initiator or a cationic polymerization initiator, but a radical polymerization initiator is preferable.

The polymerization in the polymerizing step can be carried out, for example, by performing exposure or heating using a known method depending on the polymerization initiator to be used.

Further, the polymerization in the polymerizing step may be carried out during the heating in the heating step.

Further, in the method of producing a polymer film according to the present disclosure, from the viewpoint of improving the brittleness, the polymer film obtained after the polymerizing step is contracted by preferably 0.005% by volume or greater and more preferably 0.01% by volume or greater with respect to the polymer film precursor before the polymerizing step.

Since the anchor effect is exhibited on the particle A in a case of occurrence of the contraction, the brittleness is further improved.

Forming Step

It is preferable that the method of producing the polymer film according to the present disclosure includes a forming step of forming a polymer film precursor by coating a support with a composition containing the particles, the polymer B, and a solvent and drying the composition.

The method of forming the polymer film precursor into the film shape is not particularly limited, and known methods can be referred to, and suitable examples thereof include a casting method, a coating method, and an extrusion method. Among these, the casting method is particularly preferable. Further, in a case where the polymer film has a multilayer structure, suitable examples of the method include a co-casting method, a multilayer coating method, and a co-extrusion method. Among these, the co-casting method is particularly preferable for formation of a relatively thin film, and the co-extrusion method is particularly preferable for formation of a thick film.

In a case where the multilayer structure of the polymer film is produced by the co-casting method or the multilayer coating method, it is preferable that the co-casting method or the multilayer coating method is performed by using a composition for forming the layer A, a composition for forming the layer B, or the like obtained by respectively dissolving or dispersing components of each layer such as the liquid crystal polymer in a solvent.

Examples of the solvent include a halogenated hydrocarbon such as dichloromethane, chloroform, 1,1-dichloroethane, 1,2-dichloroethane, 1,1,2,2-tetrachloroethane, 1-chlorobutane, chlorobenzene, or o-dichlorobenzene, a halogenated phenol such as p-chlorophenol, pentachlorophenol, or pentafluorophenol, an ether such as diethyl ether, tetrahydrofuran, or 1,4-dioxane, a ketone such as acetone or cyclohexanone, an ester such as ethyl acetate or γ-butyrolactone, a carbonate such as ethylene carbonate or propylene carbonate, an amine such as triethylamine, a nitrogen-containing heterocyclic aromatic compound such as pyridine, a nitrile such as acetonitrile or succinonitrile, an amide such as N,N-dimethylformamide, N,N-dimethylacetamide, or N-methylpyrrolidone, a urea compound such as tetramethylurea, a nitro compound such as nitromethane or nitrobenzene, a sulfur compound such as dimethyl sulfoxide or sulfolane, and a phosphorus compound such as hexamethylphosphoramide or tri-n-butyl phosphate. Among these, two or more kinds thereof may be used in combination.

From the viewpoints of low corrosiveness and satisfactory handleability, a solvent containing, as a main component, an aprotic compound, particularly an aprotic compound having no halogen atom is preferable as the solvent, and the proportion of the aprotic compound in the entire solvent is preferably in a range of 50% by mass to 100% by mass, more preferably in a range of 70% by mass to 100% by mass, and particularly preferably in a range of 90% by mass to 100% by mass. Further, from the viewpoint of easily dissolving the liquid crystal polymer, as the aprotic compound, an amide such as N,N-dimethylformamide, N,N-dimethylacetamide, tetramethylurea, or N-methylpyrrolidone, or an ester such as γ-butyrolactone is preferable, and N,N-dimethylformamide, N,N-dimethylacetamide, or N-methylpyrrolidone is more preferable.

From the viewpoint of easily dissolving the liquid crystal polymer, a solvent containing a compound having a dipole moment of 3 to 5 as a main component is preferable as the solvent, and the proportion of the compound having a dipole moment of 3 to 5 in the entire solvent is preferably in a range of 50% by mass to 100% by mass, more preferably in a range of 70% by mass to 100% by mass, and particularly preferably in a range of 90% by mass to 100% by mass.

It is preferable to use a compound having a dipole moment of 3 to 5 as the aprotic compound.

From the viewpoint of ease removal, a solvent containing, as a main component, a compound having a boiling point of 220° C. or lower at 1 atm is preferable as the solvent, and the proportion of the compound having a boiling point of 220° C. or lower at 1 atm in the entire solvent is preferably in a range of 50% by mass to 100% by mass, more preferably in a range of 70% by mass to 100% by mass, and particularly preferably in a range of 90% by mass to 100% by mass.

It is preferable to use a compound having a boiling point of 220° C. or lower at 1 atm as the aprotic compound.

Further, in a case where the polymer film is produced by the casting method, the co-casting method, the coating method, the multilayer coating method, the extrusion method, the co-extrusion method, or the likes, a support may be used in the method of producing the polymer film. Further, in a case where the metal layer (metal foil) or the like used in the laminate described below is used as the support, the support may be used as it is without being peeled.

Examples of the support include a metal drum, a metal band, a glass plate, a resin film, and a metal foil. Among these, a metal drum, a metal band, or a resin film is preferable.

Examples of the resin film include a polyimide (PI) film, and examples of commercially available products thereof include U-PILEX S and U-PILEX R (manufactured by Ube Corporation), KAPTON (manufactured by Du Pont-Toray Co., Ltd.), and IF30, IF70, and LV300 (manufactured by SKC Kolon PI, Inc.).

Further, the support may have a surface treatment layer formed on the surface so that the support can be easily peeled off. Hard chrome plating, a fluoropolymer, or the like can be used for the surface treatment layer.

The average thickness of the resin film support is not particularly limited, but is preferably 25 μm or greater and 75 μm or less and more preferably 50 μm or greater and 75 μm or less.

Further, the method for removing at least a part of the solvent from a cast or applied film-like composition (a casting film or a coating film) is not particularly limited, and a known drying method can be used.

Stretching Step

The method of producing the polymer film according to the present disclosure may include preferably a stretching step of stretching the polymer film precursor and more preferably a stretching step of stretching the polymer film precursor between the forming step and the heating step.

In the method of producing the polymer film according to the present disclosure, stretching can be appropriately combined from the viewpoint of controlling the molecular alignment of the film to be obtained and adjusting the linear expansion coefficient and the mechanical properties. The stretching method is not particularly limited, and a known method can be referred to, and the stretching method may be carried out in a solvent-containing state or in a dry film state. The stretching in the solvent-containing state may be carried out by gripping and stretching the film, by using a self-contractile force of a web due to drying without stretching the film, or by combining these methods. Stretching is particularly effective for the purpose of improving the breaking elongation and the breaking strength in a case where the brittleness of the film is reduced by addition of an inorganic filler or the like.

Winding Step

The method of producing the polymer film according to the present disclosure includes preferably a winding step of winding the polymer film or the polymer film precursor into a roll shape and more preferably a winding step of winding the polymer film precursor into a roll shape before the heating step and after the forming step.

It is preferable that the step of winding the film into a roll shape is performed in a nitrogen atmosphere. The amount of dissolved oxygen in the polymer film precursor can be further decreased at the start of heating the polymer film precursor by performing the step in a nitrogen atmosphere.

Unwinding Step

It is preferable that the method of producing the polymer film according to the present disclosure includes an unwinding step of unwinding the roll-shaped polymer film after the winding step.

Further, the peeling force in a case of unwinding the polymer film in the unwinding step is preferably 1.0 kN/m or less.

Peeling Step

The method of producing the polymer film according to the present disclosure includes preferably a peeling step of peeling the polymer film or the polymer film precursor from the base material after the forming step or the heating step, more preferably a peeling step of peeling the polymer film or the polymer film precursor from the base material after the forming step, and particularly preferably a peeling step of peeling the polymer film precursor from the base material after the forming step and before the heating step. The polymer film is obtained by peeling the polymer film or the polymer film precursor from the base material and thus can be used for other applications.

Other Steps

The method of producing the polymer film according to the present disclosure may include other steps in addition to the above-described steps.

Other steps may include known steps.

Laminate

A laminate according to the present disclosure may be a laminate obtained by laminating the polymer film according to the present disclosure, and the laminate includes preferably the polymer film according to the present disclosure and a metal layer or metal wire disposed on at least one surface of the polymer film and more preferably the polymer film according to the present disclosure and a copper layer or copper wire disposed on at least one surface of the polymer film.

The surface roughness Ra of the surface of the metal layer or metal wire on the side of the polymer film is preferably 1.0 μm or less and more preferably 0.5 μm or less. In a case where the surface roughness Ra is 1.0 μm or less, the surface resistance at the interface between the polymer film and the metal base material decreases.

The surface roughness Ra in the present disclosure is calculated using a surface roughness meter. For example, the surface roughness Ra is calculated in conformity with the method of calculating the arithmetic average surface roughness Ra of JIS B 0601:2013 using a stylus type surface roughness meter “SURFCORDER SE3500” (manufactured by Kosaka Laboratory Ltd.).

Further, in the measurement of the surface roughness Ra, the metal layer or the metal wire in the laminate is removed by etching with an iron chloride solution, the surface roughness Ra of the surface of the polymer film in contact with the metal layer or metal wire, to which the surface roughness of the metal layer or metal wire has been transferred, is measured, and the measured value is defined as the surface roughness Ra of the surface of the metal layer or metal wire on the side of the polymer film.

Further, the laminate according to the present disclosure includes preferably a metal layer or metal wire, the polymer film according to the present disclosure, and a metal layer or metal wire in this order and more preferably a copper layer or copper wire, the polymer film according to the present disclosure, and a copper layer or copper wire in this order.

Further, it is preferable that the laminate according to the present disclosure includes the polymer film according to the present disclosure, a copper layer or copper wire, the polymer film according to the present disclosure, a metal layer or metal wire, and the polymer film according to the present disclosure in this order. The two polymer films according to the present disclosure used for the laminate may be the same as or different from each other.

The metal layer and the metal wire are not particularly limited and may be known metal layers and metal wires, but for example, a silver layer, a silver wire, a copper layer, or a copper wire is preferable, and a copper layer or a copper wire is more preferable.

Further, it is preferable that the metal layer and the metal wire are metal wires.

Further, the metal in the metal layer and the metal wire is preferably silver or copper and more preferably copper.

The method of bonding the polymer film according to the present disclosure and the metal layer or the metal wire to each other is not particularly limited, and a known laminating method can be used.

The peel strength between the polymer film and the copper layer is preferably 0.5 kN/m or greater, more preferably 0.7 kN/m or greater, still more preferably in a range of 0.7 kN/m to 2.0 kN/m, and particularly preferably in a range of 0.9 kN/m to 1.5 kN/m.

In the present disclosure, the peel strength between the polymer film and the metal layer (for example, the copper layer) is measured by the following method.

A peeling test piece with a width of 1.0 cm is prepared from the laminate of the polymer film and the metal layer, the film is fixed to a flat plate with double-sided adhesive tape, and the strength (kN/m) in a case of peeling the film off from the metal layer at a rate of 50 mm/min is measured by the 180° method in conformity with JIS C 5016 (1994).

The metal layer is preferably a silver layer or a copper layer and more preferably a copper layer. As the copper layer, a rolled copper foil formed by a rolling method or an electrolytic copper foil formed by an electrolytic method is preferable, and a rolled copper foil is more preferable from the viewpoint of bending resistance.

The average thickness of the metal layer, preferably a copper layer, is not particularly limited, but is preferably in a range of 2 μm to 20 μm, more preferably in a range of 3 μm to 18 μm, and still more preferably in a range of 5 μm to 12 μm. The copper foil may be copper foil with a carrier formed on a support (carrier) so as to be peelable. As the carrier, a known carrier can be used. The average thickness of the carrier is not particularly limited, but is preferably in a range of 10 μm to 100 μm and more preferably in a range of 18 μm to 50 μm.

Further, from the viewpoint of further exhibiting the effects of the present disclosure, it is preferable that the metal layer contains a group that can interact with the polymer film, on the surface of the metal layer on the side in contact with the polymer film. In addition, examples of the group that can interact with the polymer film include the groups described in the section of the group forming a chemical bond, such as an amino group and an epoxy group, and a hydroxy group and an epoxy group.

Among these, from the viewpoints of adhesiveness and ease of performing a treatment, a covalently bondable group is preferable, an amino group or a hydroxy group is more preferable, and an amino group is particularly preferable.

It is also preferable that the metal layer in the laminate according to the present disclosure is processed into, for example, a desired circuit pattern by etching to form a flexible printed circuit board. The etching method is not particularly limited, and a known etching method can be used.

The method of producing the laminate according to the present disclosure is not particularly limited, but it is preferable that the method includes a laminating step of laminating the polymer film according to the present disclosure and the metal substrate.

In the laminating step, it is preferable to bond a metal wire.

A laminating method in the laminating step is not particularly limited, and a known laminating method can be used.

The bonding pressure in the laminating step is not particularly limited, but is preferably 0.1 MPa or greater and more preferably 0.2 MPa to 10 MPa.

The bonding temperature in the laminating step can be appropriately selected depending on the polymer film or the like to be used, but is preferably 150° C. or higher, more preferably 280° C. or higher, and particularly preferably 280° C. or higher and 420° C. or lower.

### EXAMPLES

Hereinafter, the present disclosure will be described in more detail with reference to examples. The materials, the used amounts, the ratios, the treatment contents, the treatment procedures, and the like described in the following examples can be appropriately changed without departing from the gist of the present disclosure. Therefore, the scope of the present disclosure is not limited to the following specific examples.

Further, “parts” and “%” are on a mass basis unless otherwise specified.

The details of the materials used in the examples and the comparative examples are as follows.

Polymer

LC-A: Liquid crystal polymer prepared by the following production method, melting point of 335° C.

Production of LC-A

940.9 g (5.0 mol) of 6-hydroxy-2-naphthoic acid, 272.8 g (2.5 mol) of 4-aminophenol, 415.3 g (2.5 mol) of isophthalic acid, and 1123.0 g (11 mol) of acetic anhydride were added to a reactor provided with a stirrer, a torque meter, a nitrogen gas introduction pipe, a thermometer, and a reflux condenser, the gas inside the reactor was substituted with nitrogen gas, and the mixture was heated from room temperature (23° C., the same applies hereinafter) to 150° C. for 15 minutes while being stirred in a nitrogen gas stream and was refluxed at 150° C. for 3 hours.

Thereafter, the mixture was heated from 150° C. to 320° C. for 3 hours while by-product acetic acid and unreacted acetic anhydride were distilled off, and the contents were taken out from the reactor at the time point when thickening was recognized and cooled to room temperature. The obtained solid matter was crushed with a crusher, thereby obtaining powdery liquid crystal polyester (B1).

The liquid crystal polyester (B1) obtained above was maintained at 250° C. for 3 hours in a nitrogen atmosphere to carry out solid phase polymerization and cooled, thereby obtaining powdery liquid crystal polyester (LC-A). The obtained LC-A was made into a film using a N-methylpyrrolidone solution, and the thermal expansion coefficient of the sample heated at 280° C. for 3 hours in a nitrogen atmosphere was 31 ppm/K and the tensile strength thereof was 100 MPa.

M-A: Low-dielectric adhesive (varnish of SLK Series (thermosetting resin, manufactured by Shin-Etsu Chemical Co., Ltd.) mainly containing polymer-type curable compound)

Particles

A-1: Liquid crystal polymer particles, melting point of 285° C., prepared by crushing commercially available type II liquid crystal polymer pellets, dielectric loss tangent of 0.002

A-2: Copolymer (PFA) particles of ethylene tetrafluoride and perfluoroalkoxy ethylene, melting point of 280° C., average particle diameter of 0.2 μm to 0.5 μm, dielectric loss tangent of 0.001

A-3: Boron nitride particles containing epoxy group on surface, melting point>500° C.

A-4: Boron nitride particles, melting point>500° C., HP40MF100 (manufactured by Mizushima Ferroalloy Co., Ltd.), dielectric loss tangent of 0.0007

The details of Examples 1 to 9 and Comparative Examples 1 to 3 are described below.

### Example 1 to 9 and Comparative Examples 1 to 3

Film Formation

A film was formed according to the following casting.

Single Layer Casting (Solution Film Formation)

Preparation of Polymer Solution

The polymer listed in Table 1 and the particles listed in Table 1 were added to N-methylpyrrolidone, and the mixture was stirred at 140° C. for 4 hours in a nitrogen atmosphere, thereby obtaining a polymer solution. The polymer and the particles were added at the volume ratio listed in Table 1, and the concentration of solid contents was 23% by mass.

Subsequently, first, the solution was allowed to pass through a sintered fiber metal filter having a nominal pore diameter of 10 μm and allowed to pass through a sintered fiber filter having a nominal pore diameter of 10 μm, thereby obtaining each polymer solution.

Preparation of Single-Sided Copper-Clad Laminated Plate

The obtained polymer solution was sent to a single-layer type casting die and cast onto a treated surface of a copper foil (CF-T4X-SV-12, manufactured by Fukuda Metal Foil & Powder Co., Ltd., average thickness of 12 μm). The solvent was removed from the cast film by drying the solvent at 40° C. for 4 hours, thereby obtaining a laminate (single-sided copper-clad laminated plate) having a copper layer and a polymer film having the thickness listed in Table 1.

Heating Step

The obtained single-sided copper-clad laminated plate was heated at the heating temperature listed in Table 1 for 10 minutes, thereby preparing a single-sided copper-clad laminated plate.

The dielectric loss tangent and the breaking elongation of the polymer film were measured using the obtained single-sided copper-clad laminated plate. The measuring method is as follows.

Dielectric Loss Tangent

The dielectric loss tangent was measured by the resonance perturbation method at a frequency of 10 GHz. A 10 GHz cavity resonator (CP531, manufactured by EM labs, Inc.) was connected to a network analyzer (“E8363B”, manufactured by Agilent Technology), and a film sample (width: 2.0 mm×length: 80 mm) was inserted into the cavity resonator, and the dielectric loss tangent of the film was measured based on a change in resonance frequency before and after the insertion in an environment of a temperature of 25° C. and a humidity 60% RH for 96 hours. Further, the copper foil was removed with ferric chloride before the measurement.

Evaluation of Breaking Elongation (Brittleness)

The polymer film was peeled off from the obtained single-sided copper-clad laminated plate, and a film sample having a length of 200 mm (measurement direction) and a width of 10 mm was cut out. The distance between chucks was set to 100 mm. The breaking elongation was calculated by performing measurement until the sample was broken in an atmosphere of a temperature of 25° C., a humidity of 60% RH, and a tensile rate of 10%/min using a universal tensile tester “STMT50BP” (manufactured by Toyo Baldwin Co., Ltd.). The brittleness of the polymer film is further improved as the value of the breaking elongation increases.

Table 1 shows the measurement results.

TABLE 1

| | Polymer film | | | | | | | | | | |
|---|---|---|---|---|---|---|---|---|---|---|---|
| | Polymer B | | | Particles | | | | | | | |
| | | Melting | Amount | | Melting | Amount | | Heating | | Breaking | Dielectric |
| | | point | (parts by | | point | (parts by | Thickness | temperature | Particles | elongation | loss |
| | Type | (° C.) | volume) | Type | (° C.) | volume) | (μm) | (° C.) | A | (%) | tangent |
| Example 1 | LC-A | 335 | 65 | A-1 | 285 | 35 | 50 | 300 | Available | 40 | 0.003 |
| Example 2 | LC-A | 335 | 50 | A-1 | 285 | 50 | 50 | 300 | Available | 35 | 0.003 |
| Comparative | LC-A | 335 | 25 | A-1 | 285 | 75 | 50 | 250 | Not | 3 | 0.004 |
| example 1 | | | | | | | | | available | | |
| Example 3 | LC-A | 335 | 25 | A-1 | 285 | 75 | 25 | 280 | Available | 26 | 0.003 |
| Example 4 | LC-A | 335 | 25 | A-1 | 285 | 75 | 25 | 300 | Available | 28 | 0.002 |
| Example 5 | LC-A | 335 | 25 | A-1 | 285 | 75 | 50 | 300 | Available | 28 | 0.002 |
| Example 6 | LC-A | 335 | 25 | A-1 | 285 | 75 | 75 | 300 | Available | 28 | 0.002 |
| Comparative | LC-A | 335 | 25 | A-1 | 285 | 75 | 50 | 330 | Not | 8 | 0.002 |
| example 2 | | | | | | | | | available | | |
| Example 7 | LC-A | 335 | 50 | A-2 | 285 | 50 | 50 | 300 | Available | 28 | 0.003 |
| Example 8 | LC-A | 335 | 50 | A-3 | >500 | 50 | 50 | 300 | Available | 18 | 0.003 |
| Comparative | LC-A | 335 | 50 | A-4 | >500 | 50 | 50 | 300 | Not | 6 | 0.003 |
| example 3 | | | | | | | | | available | | |
| Example 9 | M-A | — | 50 | A-1 | 285 | 50 | 50 | 300 | Available | 18 | 0.003 |

As listed in Table 1, the polymer films of Examples 1 to 9 were polymer films having a larger value of breaking elongation and improved brittleness than those of the polymer films of Comparative Examples 1 to 3.

### EXPLANATION OF REFERENCES

10: particle A
12a, 12b, 12c: fusion-welded particle
14a, 14b: constricted structure
16: longitudinal direction of particle A
Region A: end portion of particle A
Region B: central portion of particle A

All of documents, patent applications, and technical standards described in the present specification are incorporated into the present specification by reference to approximately the same extent as a case where it is specifically and respectively described that the respective documents, patent applications, and technical standards are incorporated by reference.

What is claimed is:

1. A polymer film, comprising:
a particle A having a constricted structure; and
a polymer B.

2. The polymer film according to claim 1, wherein the particle A comprises a particle having one or more minimum values in a central portion excluding end portions of the particle A in terms of a length of the particle A in a direction perpendicular to a longitudinal direction at at least one cross section of the particle A.

3. The polymer film according to claim 1,
wherein a melting point Tm of the particle A is 400° C. or lower.

4. The polymer film according to claim 1,
wherein a content of the particle A is 10% by volume or greater with respect to a total volume of the polymer film.

5. The polymer film according to claim 1,
wherein the particle A comprises a particle formed by fusion welding of a plurality of particles or a particle formed by bonding a plurality of particles via a chemical bond on each particle surface.

6. The polymer film according to claim 5,
wherein the particle A is the particle formed by fusion welding of a plurality of particles.

7. The polymer film according to claim 1,
wherein a dielectric loss tangent of the particle A is less than 0.01.

8. The polymer film according to claim 1,
wherein the particle A comprises at least one polymer selected from the group consisting of a fluoropolymer, a liquid crystal polymer, and polyethylene.

9. The polymer film according to claim 1,
wherein a thermal expansion coefficient of the particle A is less than a thermal expansion coefficient of the polymer B.

10. The polymer film according to claim 1,
wherein a tensile strength of the polymer B is 50 MPa or greater.

11. The polymer film according to claim 1,
wherein the polymer B has at least one bond selected from the group consisting of a urethane bond, a urea bond, an amide bond, an ester bond, an ether bond, a N—C bond, a S—C bond, and a siloxane bond.

12. The polymer film according to claim 1, further comprising:
a polymerizable compound.

13. The polymer film according to claim 12,
wherein the polymerizable compound comprises at least one group selected from the group consisting of a (meth)acryloyl group, an epoxy group, an oxetanyl group, an isocyanate group, an acid anhydride group, a carbodiimide group, a N-hydroxy ester group, a glyoxal group, an imide ester group, a halogenated alkyl group, a hydroxy group, a carboxy group, an amino group, an imidazole group, and a thiol group.

14. The polymer film according to claim 12,
wherein a content of the polymerizable compound is greater than 0% by mass and less than 5% by mass with respect to a total mass of the polymer film.

15. A laminate, comprising:
the polymer film according to claim 1; and
a metal layer or metal wire disposed on at least one surface of the polymer film.

16. A method of producing a polymer film, the method comprising:
heating a polymer film precursor comprising a particle to form, from the particle, a particle A having a constricted structure.

17. The method of producing a polymer film according to claim 16,
wherein the particle A comprises a particle having one or more minimum values in a central portion excluding end portions of the particle A in terms of a length of the particle A in a direction perpendicular to a longitudinal direction at at least one cross section of the particle A.

18. The method of producing a polymer film according to claim 16,
wherein the polymer film precursor comprises a polymerizable compound, and
the method further comprises polymerizing the polymerizable compound after the heating.

19. The method of producing a polymer film according to claim 18,
wherein the polymer film obtained after the polymerizing is contracted by 0.01% by volume or greater with respect to the polymer film precursor before the polymerizing.
